(19) United States
(12) Patent Application Publication
(10) Pub. No.: US 2008/0024332 A1
(43) Pub. Date: Jan. 31, 2008

(54) Method and Apparatus for Protecting Data

(76) Inventor: George Simonson, Deltona, FL (US)

Correspondence Address: EDELL, SHAPIRO & FINNAN, LLC, 1901 RESEARCH BOULEVARD, SUITE 400, ROCKVILLE, MD, 20850, US

(21) Appl. No.: 11/780,833

(22) Filed: Jul. 20, 2007

Related U.S. Application Data
(60) Provisional application No. 60/833,313, filed on Jul. 27, 2006.

(51) Int. Cl. H03M 5/00

(52) U.S. Cl. 341/52

(57) ABSTRACT

A data protector according to present invention embodiments protects data by assigning user-provided codes to individual data characters. Additional vowels and spaces are included in code sets and similarly associated with codes to reduce the risk of unauthorized access. Specifically, a file is selected for protection, where each data character in the selected file is verified against predetermined valid characters and subsequently assigned a user-provided code from the code sets. When the conversion is complete, the resulting output file with the codes or protected data is created and may be sent to recipient(s) in various manners (e.g., electronic mail, Snail Mail, diskette, CD, DVD, etc.). The present invention embodiments may be configured to enable the resulting output file with the protected data to be interpreted by a group or a specific individual.

### CROSS-REFERENCE TO RELATED APPLICATIONS

This application claims priority from U.S. Provisional Patent Application Ser. No. 60/833,313, entitled “Davinci Encoder/Decoder” and filed Jul. 27, 2006, the disclosure of which is incorporated herein by reference in its entirety.

### BACKGROUND OF THE INVENTION

1. Technical Field

The present invention pertains to data protection. In particular, the present invention pertains to computer systems and methods for protecting data entered from computer system keyboards or other input devices and associated with any desired spoken language (e.g., English, etc.).

2. Discussion of Related Art

Computer systems are a versatile tool and employed for both residential (e.g., consumer or personal) and commercial purposes. These computer systems store and process a voluminous amount of information depending upon the particular application. This information may contain personal or proprietary information relating to the consumer or commercial enterprise. For example, computer systems may store and/or process financial information (e.g., bank account numbers, routing information, credit card information, etc.), address information and/or other information pertaining to a consumer or business. Unauthorized possession of this consumer or commercial information may lead to significant damage or severe adverse consequences.

Accordingly, the related art provides various techniques to disguise information to prevent unauthorized access to that information. For example, U.S. Pat. No. 48,681 (Hawley) discloses a cryptographical alphabet constructed by taking thirty strips of brass or other suitable material and placing thereon two columns of letters. The first column includes twenty-six letters of the English alphabet arranged in alphabetical order with additional characters, and the second column having the same letters transposed on each successive tablet (e.g., ‘A’ is the first letter on the first tablet, ‘B’ is the first letter on the second tablet, etc.). In operation, a key-word is agreed upon and the respective tablets whose top letter in the second column corresponds to a letter in the key-word are selected. The selected tablets are utilized in order to ascertain a code for each successive letter in a message to be encoded.

U.S. Pat. No. 5,832,087 (Hawthorne) discloses an encryption/decryption apparatus that enables encrypted communication between two stations each incorporating such an apparatus. The apparatus is arranged to generate a set of look-up tables in accordance with a session key and temporarily store these tables in memory, and to convert each successive element, such as a character, of a message to a code through use of the look-up tables. The session key can be changed as often as desired but the fresh set of look-up tables are created quickly each time; then the conversion process for each element of the message is carried out quickly yet maintaining a high level of security.

U.S. Pat. No. 6,570,989 (Ohmori et al.) discloses a cryptographic processing apparatus that cryptographically processes input data using substitution table data to generate output data. A storing unit stores (2^{N}) sets of substitution data that each have a predetermined number of bits, where N is an integer no less than 2. A dividing unit divides the input data which is (N×M) bits long into M sets of N-bit subdata, where M is an integer no less than 2. A substituting unit receives an input that is any of: the M sets of N-bit subdata; and at least one set of N-bit input merged data generated by performing a merge process on the M sets of N-bit subdata. The substituting unit specifies one of the (2^{N}) sets of substitution data in the storing unit for each N bits of the input, and outputs the set of substitution data specified for each N bits of the input. A fixed conversion performing unit performs a plurality of different fixed conversions on at least one set of substitution data outputted from the substituting unit, to generate M sets of converted data that each have the predetermined number of bits. An output data generating unit generates the output data that is (N×M) bits long, based on the M sets of converted data generated by the fixed conversion performing means.

However, these techniques suffer from several disadvantages. In particular, the Hawley patent is a manual procedure that utilizes tablets embedded with the codes. Thus, the user is required to be in personal possession of the tablets in order to transfer a message. Further, the Hawley technique utilizes information in addition to the tablets (e.g., a key-word) for message transfer, thereby complicating and providing further manual user tasks and responsibilities for message transfer. Moreover, each tablet includes a single instance of the vowels, and the code for each individual letter on each tablet is primarily limited to a single character. In addition, since the tablets are successively utilized for each letter, numerous instances of the same letter within a message may produce a repeating pattern of codes for that letter. These circumstances tend to increase the risk of unauthorized or unintended recipients ascertaining the information.

The Hawthorne and Ohmori et al. patents tend to employ rigorous algorithms to encode and decode the data. For example, the Hawthorne patent generates several look-up tables based on a session key for each transference of information and utilizes each table in a chain to determine a code. This technique further requires transfer of the session key to a recipient in a protected manner to enable the recipient to generate the same tables. The Ohmori et al. patent divides and merges input data at the bit level in order to produce the converted data. Thus, these techniques utilize significant processing and complicate the procedure.

### SUMMARY OF THE INVENTION

According to present invention embodiments, a data protector protects data by assigning user-provided codes to individual data characters. Specifically, a file (e.g., word processor file, electronic mail document, etc.) is selected for protection. Each data character in the selected file is verified against predetermined valid characters and subsequently assigned a user-provided code. This process continues until all the data characters from the file have been converted or assigned a corresponding code. In particular, each character of the file is read and validated against the predetermined characters to be a valid key of a computer system keyboard. This prevents inclusion of characters in the file that may be interpreted as program code to be executed by the computer system. When the retrieved character is validated, the character is looked up in a storage structure (e.g., database, table, literal, etc.) containing associated codes for the characters. The associated code for the character is retrieved and placed in an output or protected file. The codes within the storage structure for the data characters may be pre-assigned by a user. Additional vowels and spaces are placed within the storage structure and are similarly associated with codes. Since identification of vowels and spaces contributes to code breaking of the English and/or other languages, the addition of vowels and spaces enables these characters to have no more of an identification than any other character in the particular spoken language.

When the conversion is complete, the resulting output file with the codes or protected data is created, while the contents of the original document or file may discarded and the location of the file removed from the computer system table of contents. The resulting output file with the protected data may be sent to recipient(s) in various manners (e.g., electronic mail, Snail Mail, diskette, CD, DVD, etc.). The present invention embodiments may be configured to enable the resulting output file with the protected data to be interpreted by a group or a specific individual. For example, a source may broadcast the resulting output file with the protected data to several locations worldwide, where one or more of the locations may be designated and enabled to interpret the output file. A single document or file may be converted, where each conversion may differ from the previous conversion. The codes employed are virtually unbreakable by unauthorized third parties, and each user may develop and utilize their own individual codes for assignment to the data characters.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 is a schematic diagram of an exemplary computer system employing data protection according to a present invention embodiment and in communication with other computer systems via a communications network.

FIG. 2 is a schematic illustration of exemplary arrangements for storage structures facilitating assignment of codes to data characters according to an embodiment of the present invention.

FIG. 3 is a procedural flow chart illustrating the manner in which codes are assigned to data characters according to an embodiment of the present invention.

FIG. 4 is a procedural flow chart illustrating the manner in which data characters are determined from assigned codes according to an embodiment of the present invention.

### DETAILED DESCRIPTION OF THE PREFERRED EMBODIMENTS

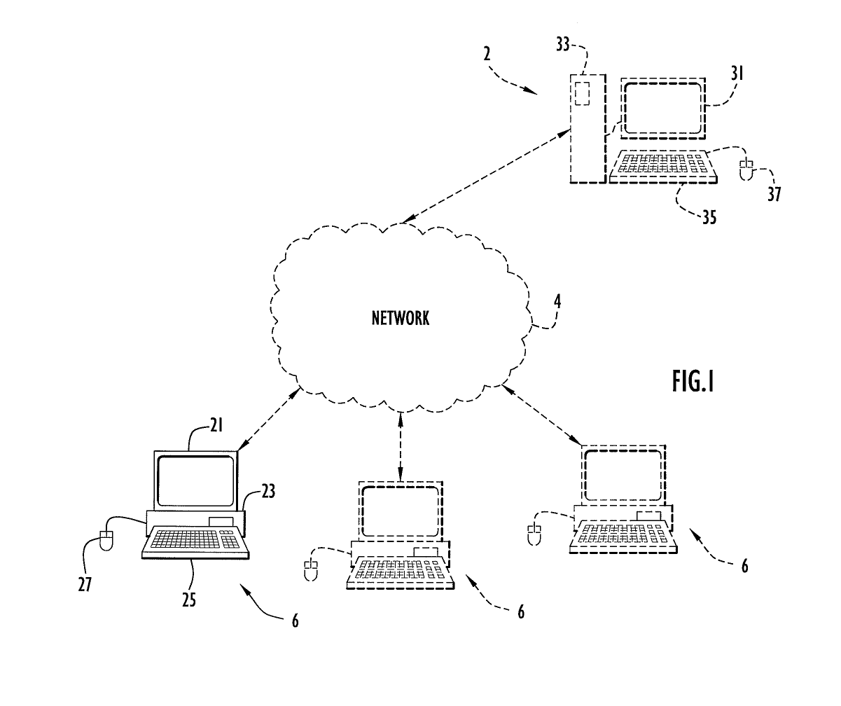

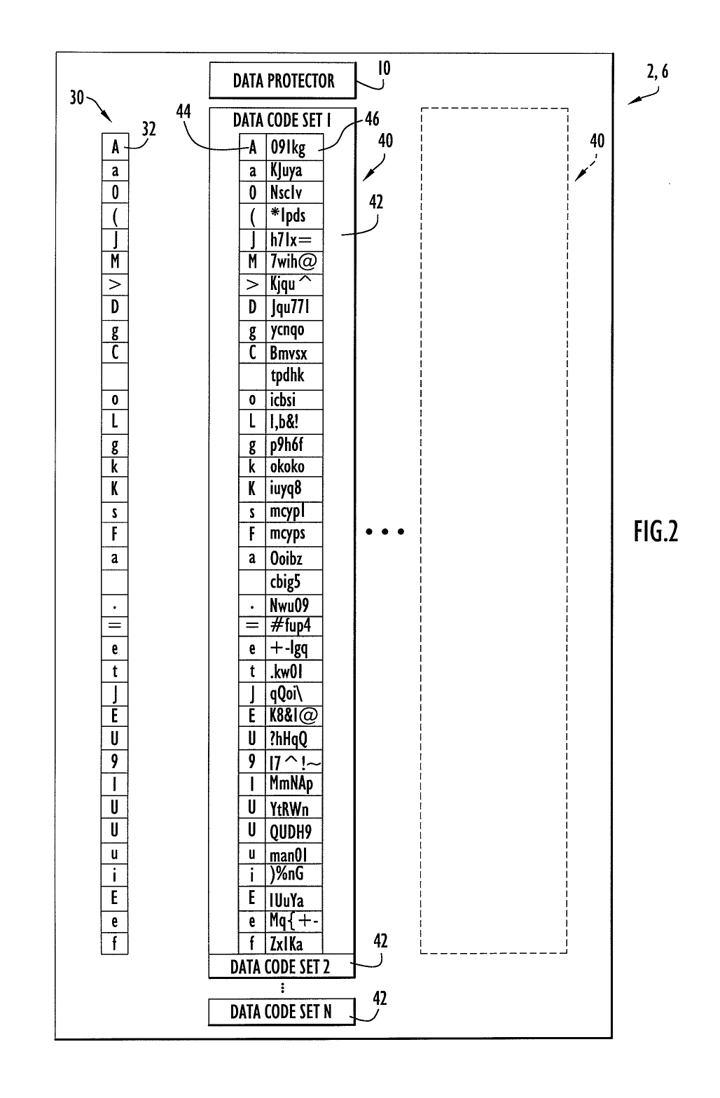

The present invention embodiments pertain to a data protector 10 (FIG. 2) for protecting data in any spoken language (e.g., English, etc.) by assigning codes to data characters entered from computer system keyboards or other input devices. The codes used by the data protector are typically pre-assigned by a user. An exemplary system configuration of one or more computer systems employing data protector 10 according to an embodiment of the present invention is illustrated in FIG. 1. Specifically, the system preferably includes a computer system 6 that may operate as a stand-alone system and employ data protector 10 (FIG. 2) to provide data protected in the manner described below. Alternatively, computer system 6 may be in communication with other computer systems 6 similarly employing data protector 10 to transfer information in a protected fashion in the manner described below. The computer systems may be in direct communications, and/or be in communication with or connected to a network 4 (e.g., the Internet, WAN, LAN, Intranet, etc.) for communication. Computer systems 6 are typically implemented by conventional personal or other suitable computer systems preferably equipped with display or monitor 21, a base 23 (e.g., including the processor, memories and internal or external communications devices (e.g., modem, network cards, etc.)), a keyboard 25 and optional mouse 27 or other input device. The computer systems each include software (e.g., operating system, Internet browser, data protector software of the present invention embodiments, etc.) to communicate and transfer information, and appropriate components (e.g., processor, disk storage or hard drive, etc.) having sufficient processing and storage capabilities to effectively execute the software.

Alternatively, a server system 2 may employ data protector 10 to transfer files with data protected in the manner described below to computer systems 6 via network 4. By way of example, the server system may provide web sites, web pages or other files to client computer systems 6 over network 4 in a protected manner (e.g., to facilitate secure web sites or pages or other files, etc.). Server system 2 is typically implemented by a conventional personal or other suitable computer system preferably equipped with a display or monitor 31, a base 33 (e.g., including the processor, memories and internal or external communication devices (e.g., modem, network cards, etc.)), a keyboard 35 and optional mouse 37 or other input device. The server system includes software (e.g., operating system, server software, data protector software of the present invention embodiments, etc.) to communicate with computer systems 6 and process web or other requests, and appropriate components (e.g., processor, disk storage or hard drive, etc.) having sufficient processing and storage capabilities to effectively execute the software. The computer and server systems may utilize any of the commercially available operating systems and/or other software and, under software control, may each implement a respective data protector 10 of the present invention embodiments for protecting data.

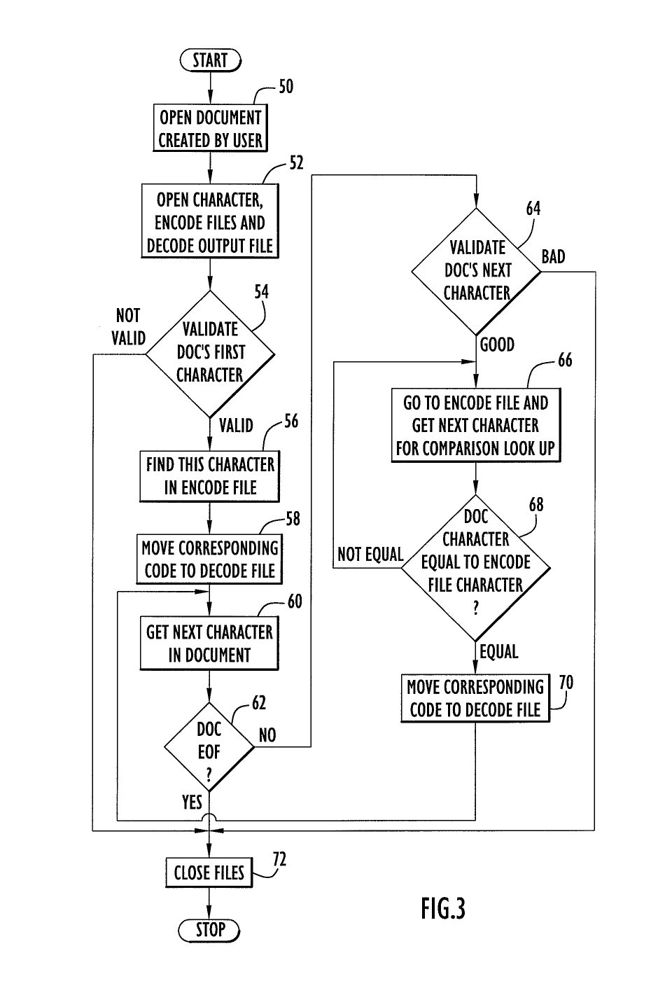

The manner in which data protector 10 protects data according to an embodiment of the present invention is illustrated in FIGS. 2-3. Initially, data protector 10 utilizes a series of data stores 30, 40 to protect information. These data stores may be implemented by any type of any conventional or other storage or data structures (e.g., tables, arrays, lists, stacks, memories, databases, queues, files, etc.). Data store 30 includes a plurality of fields 32 each corresponding to and containing an individual character (e.g., alphanumeric, punctuation or symbols, etc.) associated with a desired spoken language (e.g., English, etc.). Data store 30 may be generated manually by the user and/or by a processing device (e.g., computer system, etc.). The characters in data store 30 may be arranged in any desired or suitable order. For example, the characters may include each of the keyboard keys available to an end-user. This set includes approximately ninety-four characters for an English-language based keyboard, where a character arrangement may include: capitalized alphabetic characters (e.g., ‘A’ to ‘Z’); lower case alphabetic characters (e.g., ‘a’ to ‘z’); numeric characters (e.g., ‘0’ to ‘9’); a space; a carriage return (e.g., enter key); and remaining characters of the keyboard. When a file for data protection is read, each character retrieved from the file is validated against the characters within data store 30 to verify that the retrieved character is a valid character (e.g., from the corresponding keyboard or other input device) as described below.

Data store 40 enables codes to be assigned to data characters within information to be protected and to retrieve original information from protected data (in the form of a sequence of assigned codes). Thus, the information within data store 40 is accessible to computer (and/or server) systems of senders and recipients of protected information (e.g., via access to data store 40, copies of data store 40 resident on the respective computer (or server) systems, etc.). Data store 40 includes a plurality of data code sets 42 (e.g., indicated as Data Code Set 1 to Data Code Set N in FIG. 2). Each data code set includes a plurality of character fields 44 and corresponding code fields 46. Character fields 44 each correspond to and contain an individual character (e.g., alphanumeric, punctuation or symbols, etc.) associated with a desired spoken language (e.g., English, etc.), while fields 46 are each associated with a corresponding character field 44 and contain a code for the individual character within the associated character field. Each data code set 42 is basically a mirror image of data store 30, where character fields 44 include the individual characters of fields 32. The individual characters from data store 30 are preferably repeated within data store 40 a minimum of six times. In other words, data store 40 preferably includes at least six data code sets 42 (e.g., N=6 as viewed in FIG. 2) each containing the individual characters within data store 30. By way of example, data store 40 for an English-based keyboard with six data code sets may include 564 characters or entries (e.g., 94 characters×6 data code sets=564 characters). However, any quantity of data code sets may be utilized to assign codes to data characters in the manner described below.

The characters within the various data codes sets of data store 40 may be arranged in any order, where the character order is preferably varied across the data code sets. For example, a first data code set may include a character arrangement of: numeric characters (e.g., ‘0’ to ‘9’); capitalized alphabetic characters (e.g., ‘A’ to ‘Z’); special characters; a space; lower case alphabetic characters (e.g., ‘a’ to ‘z’); and a carriage return (e.g., enter). A second data code set may include a character arrangement of: numeric characters (e.g., in reverse order from ‘9’ to ‘0’); special characters; capitalized alphabetic characters (e.g., in reverse order from ‘Z’ to ‘A’); lower case alphabetic characters (e.g., in reverse order from ‘z’ to ‘a’). The remaining data code sets may include any suitable variations of these arrangements.

Further, data store 40 includes additional characters within each data code set to prevent ascertainment of protected information. In particular, extra vowels are inserted within the data code sets in addition to the vowels already included therein. Preferably, four or five additional vowels in both capitalized and lower case form are added to each of the data code sets. Moreover, at least five additional space (or space bar) characters are added to each data code set. Since identification of vowels and spaces contributes to code breaking of the English and/or other languages, the addition of vowels and spaces enables these characters to have no more of an identification than any other character in the particular spoken language. These additional characters may be placed at any suitable locations within the character arrangements of the data code sets. However, any quantity of any types of additional characters may be added to one or more of the data code sets at any desired locations.

Once the characters within the data code sets are arranged, a corresponding code is associated with each data character in the data code set (e.g., including the additional characters inserted therein). Generally, the codes are unique across the data code sets and non-sequential code values within the data code sets decrease the risk of unauthorized access of the protected information. The corresponding codes may be of any desired length and include any individual or combinations of characters, where the code length is preferably maintained across the data code sets. The individual characters for the codes preferably correspond to the characters of the keyboard or other input device. By way of example, the first data code set illustrated in FIG. 2 includes a substantially random arrangement of data characters within fields 44 with each corresponding code including five characters from an English language based keyboard. This code length is utilized for codes in each of the remaining data code sets (e.g., Data Code Set 2 to Data Code Set N as viewed in FIG. 2). However, the codes may include any quantity of any types of characters.

Once a data character is retrieved from the file for data protection and validated against data store 30, the corresponding code for that character is identified in data store 40 from one of the data code sets as described below. The identified code is written to a resulting output file or storage structure, while identification of a code for a successive data character commences at the location within data store 40 immediately following the location of the previously identified character. In this fashion, the data code sets are traversed successively (e.g., and wrap around (from Data Code Set N to Data Code Set 1 as viewed in FIG. 2)) to identify and assign codes to data characters for placement in the output file. The identified codes for the retrieved data characters are placed in the output file directly adjacent each other (e.g., without spaces therebetween). For example, data store 40 (e.g., as viewed in FIG. 2) produces the code ‘Bmvsxooibz.kw01’ for the word ‘Cat’.

Since the codes within data store 40 are typically determined by the user, each individual user may create a data store 40 with their own personal codes to protect data specifically for their applications. Further, a user may create several data stores 40 each with different codes or character arrangements to provide protection for various recipients or transfers. In particular, the present invention embodiments may employ a plurality of data stores 40 to provide different versions of protected data within a file for different recipients. This enables production of files with protected data targeted to (e.g., and able to be ascertained by) a specific recipient or one or more groups of recipients. For example, each division within a company, agency or other entity may utilize a different data store 40 (e.g., data stores 40 with different arrangements of characters and codes, different codes, etc.). This enables a higher level manager to provide a protected file specific to a particular division (e.g., without the other divisions being able to decode the file). Moreover, a user may utilize a different data store 40 for each individual or group of recipients. The recipients of the protected information need a copy of or access to data store 40 utilized to assign the codes in order to ascertain the original information.

Referring to FIG. 3, data protector 10 utilizes data stores 30, 40 to protect information and to retrieve original information from a sequence of codes. Initially, a file (e.g., word processing file, web page, document, etc.) is created by a user and contains information for protection by data protector 10. The created file is opened at step 50, while data store 30, the appropriate data store 40 (e.g., for a particular recipient or group of recipients, etc.) and an output file to receive codes from data store 40 assigned to the data characters within the file are opened at step 52. Data store 40 may be selected to produce the output file targeted to specific recipients as described above. Specifically, an initial data character is retrieved from the file and validated against the individual characters within data store 30 (FIG. 2) at step 54. If the retrieved data character is absent from data store 30 as determined at step 54, this indicates an invalid character and the opened structures or files (e.g., data stores, user-created file, output file, etc.) are closed at step 72 and processing terminates.

Otherwise, when the retrieved data character is valid as determined at step 54, the corresponding code for the retrieved character is identified in data store 40 at step 56 and placed in the output file at step 58. In particular, each individual character from data store 40 is retrieved and compared to the retrieved data character. This initial search typically commences from the first location in data store 40 (e.g., commences with the first character of the first data code set). The individual characters within data store 40 are retrieved from character fields 42 (FIG. 2) sequentially and from successive data code sets (e.g., wrapping around from Data Code Set N to Data Code Set 1 as viewed in FIG. 2) until the retrieved character is located within data store 40. The location of the retrieved character within data store 40 is stored in order to determine an initial location within data store 40 to search for the next character retrieved from the file. The search for the next retrieved character commences at the location immediately following the previous or stored location as described below.

The next character from the file is retrieved at step 60. When the file is empty as determined at step 62, the opened structures or files (e.g., data stores, user-created file, output file, etc.) are closed at step 72 and processing terminates as described above.

If the file is not empty, the retrieved data character is validated against the characters within data store 30 (FIG. 2) at step 64 as described above. If the retrieved character is absent from data store 30 as determined at step 64, this indicates an invalid character and the opened structures or files (e.g., data stores, user-created file, output file, etc.) are closed at step 72 and processing terminates as described above. When the character is valid, the next character from data store 40 is identified at step 66. In particular, the search for the next character in data store 40 starts at the location or address immediately following the location where the previous character was identified. This may be determined from the location stored after the prior character search within data store 40 as described above. For example, when the previous character is identified at location or address fifteen in data store 40, the search for a successive character commences at the immediately following location, or location sixteen in data store 40. In other words, a search for a retrieved data character commences from one more than the immediately previous location in data store 40 (e.g., the address following the last location or address). In this fashion, each of the data code sets are utilized in succession (e.g., and wrap around from Data Code Set N to Data Code Set 1 as viewed in FIG. 2) to identify codes for characters retrieved from the file.

If the character retrieved from data store 40 is the same as the data character retrieved from the file as determined at step 68, the associated code (in field 44) from data store 40 is assigned to the data character retrieved from the file and placed in the output file at step 70. The location within data store 40 of the matching character is stored in order to commence a search for the next character retrieved from the file as described above.

Alternatively, an offset may be applied to identify a code within data store 40 for a character retrieved from the file. The offset value is determined prior to commencing the search for a code within data store 40. In particular, when a character retrieved from data store 40 is the same as the character retrieved from the file, the address or location of the character within data store 40 is modified by the offset and the code for a character at the newly determined address (e.g., address of identified character+offset) is assigned to the retrieved character and placed in the output file. For example, the address for a matching character within data store 40 may be 100. This address is modified by the offset to identify a corresponding code. If the offset value was positive two, the code located at address 102 is assigned to the retrieved character and placed in the output file. If the offset value was a negative two, the code located at address 98 is assigned to the retrieved character and placed in the output file. The offset value typically has a maximum value of one less than the total length of data store 40. If the combination of the offset and address of the matching character resides outside the address space of the data code sets within data store 40, the resulting address is determined in a manner to wrap around the data code sets (e.g., a modulo operation is performed to determine the resulting address, etc.). The location within data store 40 of the matching character is stored in order to commence a search for the next character retrieved from the file as described above.

When the characters retrieved from the data store and file are not the same, the next character (e.g., the character in data store 40 immediately following the previously retrieved character) is retrieved at step 66 and compared to the data character retrieved from the file at step 68. This retrieval process (e.g., steps 66 and 68) repeats until the character retrieved from the file is located in data store 40. Once a character retrieved from data store 40 is the same as the character retrieved from the file, the associated code from data store 40 (or code derived from an offset) is assigned to the data character and placed in the output file at step 70 as described above. The location within data store 40 of the matching character is stored in order to commence a search for the next character retrieved from the file as described above.

The above process of retrieving characters from the file and assigning codes from data store 40 (e.g., steps 60, 62, 64, 66, 68 and 70) is repeated until the file is empty as determined at step 62. Once this occurs, the resulting output or protected file may be created and named. The output file may further be sent safely to a desired destination (e.g., electronic mail, Snail Mail, diskette, CD, DVD, etc.).

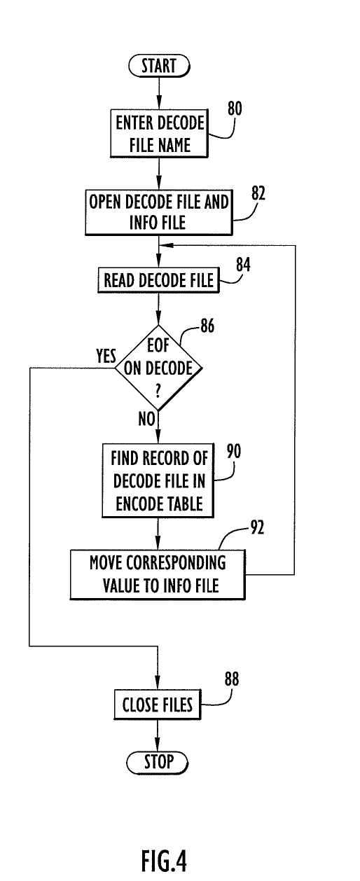

The manner in which data protector 10 ascertains original information from a sequence of codes in a protected file is illustrated in FIG. 4. Initially, when a file with protected data (e.g., word processing file, web site or web page, document, etc.) is provided to a recipient, the recipient computer system typically utilizes data protector 10 to ascertain the original information in response to receiving an indication that a new file is being received. This is typically accomplished by the user providing the file name of the received output or protected file. The recipient may further destroy the received protected file once the original information has been ascertained. In order to ascertain the original information from the protected file, the recipient needs a copy of or access to data store 40 used to derive the codes in the received protected file. This data store may be one of a plurality of data stores utilized to produce a protected file for specific recipients as described above. Specifically, data protector 10 prompts a user for the name of a file (e.g., word processing file, etc.) containing the protected information at step 80 and opens the protected file, an output or information file and an appropriate data store 40 (e.g., opens a copy of data store 40, accesses information in data store 40, etc.) at step 82. Alternatively, data protector 10 may be automatically invoked to handle a protected file (e.g., in the case of receiving a web page or other files electronically, etc.).

A code from the protected file is retrieved at step 84. When the protected file is empty as determined at step 86, the opened structures or files (e.g., data stores, received protected file, information file, etc.) are closed at step 94 and processing terminates. Otherwise, data store 40 is utilized to identify the character associated with the retrieved code at step 90. In particular, each individual code from data store 40 is retrieved and compared to the code retrieved from the protected file. Since the codes within data store 40 are preferably unique, the search for each code retrieved from the file commences from the first location in data store 40 (e.g., commences with the first code of the first data code set). The codes within data store 40 are retrieved from code fields 44 (FIG. 2) sequentially and from successive data code sets (e.g., wrapping around from Data Code Set N to Data Code Set 1 as viewed in FIG. 2) until the retrieved code is located within data store 40.

When the codes in data store 40 are not unique, the codes retrieved from the protected file are located in substantially the same manner described above for locating characters in data store 40 to assign codes. In particular, a search for an initial code retrieved from the protected file commences from the first location in data store 40 (e.g., commences with the first code of the first data code set). The location within data store 40 containing the code retrieved from the protected file is stored to determine the location for commencing the next code search. The search for the next code retrieved from the protected file in data store 40 starts at the location or address immediately following the location where the previous code was identified. This may be determined from the location stored after the prior code search within data store 40. For example, when the previous code is identified at location or address fifteen in data store 40, the search for a successive code commences at the immediately following location, or location sixteen in data store 40. In other words, a search for a retrieved code commences from one more than the immediately previous location in data store 40 (e.g., the address following the last location or address). In this fashion, each of the data code sets are utilized in succession (e.g., and wrap around from Data Code Set N to Data Code Set 1 as viewed in FIG. 2) to identify characters for codes retrieved from the file.

In the case of utilization of an offset, when a code is identified in data store 40, the presence of an offset is determined. If an offset exists, the offset is applied to the location of the identified code within data store 40 to retrieve the appropriate character. Since the resulting code was displaced from the character in data store 40 by the offset value as described above, the inverse of the offset is applied to the location of the retrieved code (e.g., the offset is applied in a reverse manner) to ascertain the character in data store 40. For example, a code is identified at location or address 98 in data store 40. If a negative two was used as an offset value to provide the code, the inverse offset of positive two is applied to location 98 to retrieve the resulting character at address or location 100. If the combination of the offset and address of the matching code resides outside the address space of the data code sets within data store 40, the resulting address is determined in a manner to wrap around the data code sets (e.g., a modulo operation is performed to determine the resulting address, etc.) as described above.

Once a code retrieved from the protected file is located in data store 40, the corresponding character is placed in the information file at step 92 and the next code is retrieved from the protected file at step 84. This process is repeated (e.g., steps 84, 86, 90, and 92) until the file is empty as determined at step 86. Once the protected file has been totally processed, the resulting information file may be saved, displayed and/or printed.

The present invention embodiments may employ a plurality of data stores 40 to provide different versions of a protected file for different recipients as described above. Alternatively, offsets may similarly be utilized to produce protected files targeted for specific recipients. The offset is utilized to produce the protected file and to enable the protected file to be read by specific recipients. For example, an offset may be utilized to produce a protected file for a group or an individual. In this case, only the recipients with knowledge of the offset are able to properly utilize data store 40 to ascertain the original information from the protected file. The offset may be configured into the data protector (e.g., in software or hardwired), or passed to a recipient via a variable or parameter.

The data protector may be utilized with information in any desired spoken language, especially those utilized for computer system keyboards or other input devices. Further, the data protector of the present invention embodiments may be utilized on various processing devices or platforms and for various applications. For example, the data protector may be utilized for transference, transmission and/or communication for any types of data (e.g., packets, programs, documents, web pages, audio, video, image, etc.). In the case of raw data (e.g., digitized voice, video, image, etc.) or other data not associated with characters, the data bits may be grouped into data words (e.g., containing a desired quantity of bits) with each data word converted to a corresponding character based on a coding scheme (e.g., ASCII, EBCDIC, user-generated scheme where a value represented by the bits in a data word is associated with a character, etc.). The resulting characters may be protected in the manner described above, where the original characters are retrieved from the protected file and converted back to the raw data via the coding scheme. By way of example, the data protector may be utilized in processing devices of cellular telephones or other wireless devices to transfer protected voice or other information (e.g., text messaging, etc.).

It will be appreciated that the embodiments described above and illustrated in the drawings represent only a few of the many ways of implementing a method and apparatus for protecting data.

The data processing systems (e.g., computer system, server, etc.) employed by the present invention embodiments may be implemented by any quantity of any personal or other type of computer system (e.g., IBM-compatible, Apple, Macintosh, laptop, palm pilot, etc.), and may include any commercially available operating system (e.g., Windows, OS/2, Unix, Linux, etc.) and any commercially available or custom software (e.g., browser software, communications software, data protector software, etc.). These systems may include any types of monitors to view information, and any types of input devices (e.g., keyboard, mouse, voice recognition, etc.) to enter information in any desired spoken language (e.g., English, Spanish, Japanese, Korean, French, Chinese, etc.) for data protection. The characters for data protection may be any suitable characters associated with a spoken language and/or corresponding to a keyboard or other input device of that language (e.g., alphanumeric, symbols, punctuations, special characters, carriage return or enter, space, etc.).

It is to be understood that the software (e.g., data protector software, etc.) for the data processing systems of the present invention embodiments (e.g., computer systems, server, etc.) may be implemented in any desired computer language and could be developed by one of ordinary skill in the computer arts based on the functional descriptions contained in the specification and flow charts illustrated in the drawings. Further, any references herein of software performing various functions generally refer to computers or processors performing those functions under software control. The data processing systems of the present invention embodiments may alternatively be implemented by any type of hardware and/or other processing circuitry. The various functions of the data processing systems (or data protector) may be distributed in any manner among any quantity of software modules or units, processing or computer systems and/or circuitry, where the processing systems may be disposed locally or remotely of each other and communicate via any suitable communications medium (e.g., LAN, WAN, Intranet, Internet, hardwire, modem connection, wireless, etc.). For example, the functions of the present invention embodiments may be distributed in any manner among the computer systems and server. Moreover, the data protector may include individual modules or units for assigning the codes, producing the original information and other functions. The data processing systems may perform any individual or combinations of these functions (e.g., a sending system may only produce the protected file while a receiving system may only retrieve the original information, sending and receiving systems may both produce the protected file and retrieve original information, etc.). The software and/or algorithms described above and illustrated in the flow charts may be modified in any manner that accomplishes the functions described herein. In addition, the functions in the flow charts or description may be performed in any order that accomplishes a desired operation.

The software of the present invention embodiments may be available on a recordable medium (e.g., magnetic or optical mediums, magneto-optic mediums, floppy diskettes, CD-ROM, DVD, memory devices, program product or other apparatus or device with the recordable medium, etc.) for use on stand-alone systems or systems connected by a network or other communications medium, and/or may be downloaded (e.g., in the form of carrier waves, packets, etc.) to systems via a network or other communications medium.

The communication network may be implemented by any quantity of any type of communications network (e.g., LAN, WAN, Internet, Intranet, VPN, etc.). The processing systems of the present invention embodiments (e.g., computer systems, server, etc.) may include any conventional or other communications devices to communicate over the network via any conventional or other protocols. The processing systems may utilize any type of connection (e.g., wired, wireless, etc.) for access to the network.

The data stores may be implemented by any quantity of any type of conventional or other storage or data structures (e.g., tables, arrays, lists, stacks, memories, databases, queues, files, etc.), and may reside on any suitable data processing systems accessible to sending and receiving machines (e.g., sending and/or receiving computer systems or server, third party systems, etc.). The data stores may be implemented as a single combined data store or as two or more data stores to contain the information. Data store 30 may include any quantity of any types of fields or storage locations to contain any quantity of any types of characters (e.g., alphanumeric, symbols, punctuations, special characters, carriage return or enter, space, etc.) associated with any spoken language. The characters may be arranged in any desired order within data store 30. This data store may be traversed in any desired direction, order or fashion (e.g., sequentially, randomly, any offsets, etc.) to search for a character.

Data store 40 may include any quantity of any types of fields or storage locations to contain any quantity of any types of characters (e.g., alphanumeric, symbols, punctuations, special characters, carriage return or enter, space, etc.) associated with any spoken language, and any types of corresponding codes. The characters may be arranged in any desired order within data store 40. This data store may include any quantity of data code sets or repeating sets of the characters. The characters within the repeated sets may be arranged in any desired order or fashion and preferably vary across the repeated character sets.

The codes may be of any length and include any quantity of any types of characters (e.g., alphanumeric, symbols, punctuations, special characters, carriage return or enter, space, etc.). The length for each code is preferably the same, but may vary in any desired fashion. Any quantity of any additional characters (e.g., consonants, vowels, spaces, special characters, punctuation, symbols, etc.) may be inserted within one or more character sets at any desired locations to reduce risk of unauthorized access. The codes may be assigned manually by a user, or produced by a processing system (e.g., random generation, etc.). The codes are preferably unique among each individual character entry (e.g., each entry is associated with a different code) to provide maximum protection, but may be duplicated in any fashion.

Data store 40 may be traversed in any desired direction, order or fashion (e.g., sequentially, randomly, any offsets, etc.) to search for a character or code. The search for a next character or code may commence from any displaced location from the location including the character for the prior search (e.g., immediately following or preceding location, any offset from that location, etc.). Codes may be retrieved from data store 40 in any desired manner. For example, a code may be retrieved from a code field adjacent or displaced by any desired offset from a corresponding character. In other words, the offsets may include any desired values.

Data store 40 may be of any quantity, where each data store may include different character arrangements and/or codes. The data stores may be utilized to target protected information for a specific recipient or one or more groups of recipients. Alternatively, the same data store may be utilized with different offsets for specific recipients to target protected information for a specific recipient or one or more groups of recipients. The specific offsets and data stores 40 are known by the targeted recipients (e.g., accessible to the recipient system, copies reside on the recipient system, the offset or data store is configured or hardwired into the data protectors of the sending and receiving systems, etc.).

The data protector of the present invention embodiments may receive information in any desired data or storage structure (e.g., file, array, list, queue, record, stack, etc.) and provide the output in any desired data or storage structure (e.g., file, array, list, queue, record, stack, etc.). The information and output may be in any desired format or arrangement (e.g., codes or characters adjacent each other, spaced apart, etc.). Further, the data protector may protect raw information (e.g., digitized images, audio, video, etc.) or information unassociated with characters. In this case, the data bits may be grouped into data words (e.g., including a desired quantity of bits), where the values of the data words may be utilized to determine corresponding characters from a character or other coding scheme (e.g., ASCII, EBCDIC, user-generated, etc.). The resulting characters are protected as described above. The original information is ascertained by retrieving the characters and converting the characters back to the data words or bits.

The present invention embodiments are not limited to the applications disclosed herein, but may be utilized for protection or transference of any suitable information (e.g., web pages, cellular or wireless transmissions, text messaging, packet transmissions, voice, audio, image, etc.).

The present invention embodiments may provide various messages or other indications to a user relating to the type of processing termination, conditions or other events (e.g., invalid initial or subsequent characters, end of file for retrieving characters or codes from original or protected information, successful conversion, output file name/location, etc.). The messages may include any suitable information or data relating to the processing or system conditions.

From the foregoing description, it will be appreciated that the invention makes available a novel method and apparatus for protecting data, wherein data is protected by assigning user-provided codes to individual data characters.

Having described preferred embodiments of a new and improved method and apparatus for protecting data, it is believed that other modifications, variations and changes will be suggested to those skilled in the art in view of the teachings set forth herein. It is therefore to be understood that all such variations, modifications and changes are believed to fall within the scope of the present invention as defined by the appended claims.

What is claimed is:

1. A system for protecting information including individual data characters from a character set comprising:
a processing system to assign codes to individual data characters within said information and including:
a code data store to store a plurality of data code sets each including said character set and a corresponding code for each said character within said character set;
a search module to retrieve each individual data character from said information and to identify a location within said code data store of each said retrieved character, wherein each search for a successive retrieved character from said information identifies the next occurrence of said successive retrieved character within said code data store relative to said identified location of an immediately preceding character; and
a code assign module to identify a code in said code data store corresponding to each retrieved character and to assign said identified codes to said corresponding characters retrieved from said information to produce protected information in the form of a sequence of said assigned codes.

2. The system of claim 1, wherein said processing system further includes:
a character data store to store said characters of said character set;
wherein said search module includes:
a verification module to verify said retrieved data characters against said character data store and facilitate identification of said location of a retrieved character in said code data store in response to verification of that character.

3. The system of claim 1, wherein said corresponding codes for said characters within said code data store are determined by a user.

4. The system of claim 1, wherein said codes each include at least one of an alphanumeric character, a punctuation character, a space character, a carriage return character and a symbol.

5. The system of claim 1, wherein said code assign module includes:
an offset module to apply an offset to said identified location of a retrieved character within said code data store to determine a location of said corresponding code for that character.

6. The system of claim 1, wherein said information includes one of a web page, an electronic mail message and a word processing document, and said characters within said character set correspond to characters of a computer system keyboard.

7. The system of claim 1, wherein at least one data code set includes at least one duplicate character, and wherein said duplicate character includes at least one of a vowel and a space character.

8. The system of claim 1, wherein said processing system further includes:
a code module to receive said protected information in the form of said sequence of codes and to locate each code within said code data store and determine a corresponding character for that code to reproduce said information.

9. The system of claim 1, wherein said processing system includes a plurality of said code data stores each associated with a specific recipient to produce protected information discernable by that recipient.

10. The system of claim 1, wherein said processing system further includes:
a data module to group data into a plurality of data words and to convert each data word to a corresponding data character based on a value of that data word to form said information.

11. A program product apparatus including a computer readable medium with computer program logic recorded thereon for protecting information including individual data characters from a character set, said program product apparatus comprising:
a code data store to store a plurality of data code sets each including said character set and a corresponding code for each said character within said character set;
a search module to retrieve each individual data character from said information and to identify a location within said code data store of each said retrieved character, wherein each search for a successive retrieved character from said information identifies the next occurrence of said successive retrieved character within said code data store relative to said identified location of an immediately preceding character; and
a code assign module to identify a code in said code data store corresponding to each retrieved character and to assign said identified codes to said corresponding characters retrieved from said information to produce protected information in the form of a sequence of said assigned codes.

12. The apparatus of claim 11, further including:
a character data store to store said characters of said character set;
wherein said search module includes:
a verification module to verify said retrieved data characters against said character data store and facilitate identification of said location of a retrieved character in said code data store in response to verification of that character.

13. The apparatus of claim 11, wherein said corresponding codes for said characters within said code data store are determined by a user.

14. The apparatus of claim 11, wherein said codes each include at least one of an alphanumeric character, a punctuation character, a space character, a carriage return character and a symbol.

15. The apparatus of claim 11, wherein said code assign module includes:
an offset module to apply an offset to said identified location of a retrieved character within said code data store to determine a location of said corresponding code for that character.

16. The apparatus of claim 11, wherein said information includes one of a web page, an electronic mail message and a word processing document, and said characters within said character set correspond to characters of a computer system keyboard.

17. The apparatus of claim 11, wherein at least one data code set includes at least one duplicate character, and wherein said duplicate character includes at least one of a vowel and a space character.

18. The apparatus of claim 11, further including:
a code module to receive said protected information in the form of said sequence of codes and to locate each code within said code data store and determine a corresponding character for that code to reproduce said information.

19. The apparatus of claim 11, further including:
a plurality of said code data stores each associated with a specific recipient to produce protected information discernable by that recipient.

20. The apparatus of claim 11, further including:
a data module to group data into a plurality of data words and to convert each data word to a corresponding data character based on a value of that data word to form said information.

21. A method for protecting information including individual data characters from a character set comprising:
(a) storing in a code data store a plurality of data code sets each including said character set and a corresponding code for each said character within said character set;
(b) retrieving each individual data character from said information and identifying a location within said code data store of each said retrieved character, wherein each search for a successive retrieved character from said information identifies the next occurrence of said successive retrieved character within said code data store relative to said identified location of an immediately preceding character; and
(c) identifying a code in said code data store corresponding to each retrieved character and to assign said identified codes to said corresponding characters retrieved from said information to produce protected information in the form of a sequence of said assigned codes.

22. The method of claim 21, wherein step (a) further includes:
(a.1) storing said characters of said character set in a character data store; and step (b) further includes:
(b.1) verifying said retrieved data characters against said character data store and facilitating identification of said location of a retrieved character in said code data store in response to verification of that character.

23. The method of claim 21, wherein said corresponding codes for said characters within said code data store are determined by a user.

24. The method of claim 21, wherein said codes each include at least one of an alphanumeric character, a punctuation character, a space character, a carriage return character and a symbol.

25. The method of claim 21, wherein step (c) further includes:
(c.1) applying an offset to said identified location of a retrieved character within said code data store to determine a location of said corresponding code for that character.

26. The method of claim 21, wherein said information includes one of a web page, an electronic mail message and a word processing document, and said characters within said character set correspond to characters of a computer system keyboard.

27. The method of claim 21, wherein at least one data code set includes at least one duplicate character, and wherein said duplicate character includes at least one of a vowel and a space character.

28. The method of claim 21, further including:
(d) receiving said protected information in the form of said sequence of codes and locating each code within said code data store to determine a corresponding character for that code and reproduce said information.

29. The method of claim 21, wherein step (a) further includes:
(a.1) selecting one of a plurality of said code data stores each associated with a specific recipient to produce protected information discernable by that recipient.

30. The method of claim 21, wherein step (a) further includes:
(a.1) grouping data into a plurality of data words and converting each data word to a corresponding data character based on a value of that data word to form said information.
